(19) United States
(12) Patent Application Publication
(10) Pub. No.: US 2026/0223714 A1
(43) Pub. Date: Jul. 30, 2026

(54) SEMICONDUCTOR CHIP ALIGNMENT METHOD, BONDING METHOD, ELECTRONIC COMPONENT MANUFACTURING DEVICE, AND ELECTRONIC COMPONENT MANUFACTURING SYSTEM

(71) Applicants: YAMAHA ROBOTICS HOLDINGS CO., LTD., Tokyo (JP); Tokyo University of Science Foundation, Tokyo (JP)

(72) Inventors: Hiroshi KIKUCHI, Tokyo (JP); Jin LI, Tokyo (JP); Norimasa NAGATA, Tokyo (JP); Masaaki MIYATAKE, Tokyo (JP)

(73) Assignees: YAMAHA ROBOTICS HOLDINGS CO., LTD., Tokyo (JP); Tokyo University of Science Foundation, Tokyo (JP)

(21) Appl. No.: 19/145,899

(22) PCT Filed: Jan. 6, 2023
(86) PCT No.: PCT/JP2023/000129

§ 371 Date: Jul. 4, 2025

(51) Int. Cl. H10W 72/00

(52) U.S. Cl. CPC H10W 72/07221; H10W 72/07178; H10W 72/07233

(57) ABSTRACT

An alignment method for a first semiconductor chip (221) and a second semiconductor chip (231) to be stacked, wherein the first semiconductor chip (221) is ultrasonically vibrated, a lower surface (231a) of the second semiconductor chip (231) is brought close to an upper surface (221a) of the first semiconductor chip (221) so as to overlap the first semiconductor chip (221) that is vibrating ultrasonically and the second semiconductor chip (231) is released to self-align the second semiconductor chip (231) on the first semiconductor chip (221).

### TECHNICAL FIELD

The invention relates to an alignment method for semiconductor chips to be stacked, a bonding method, an electronic component manufacturing device, and a configuration of an electronic component manufacturing system.

### RELATED ART

A method is used in which a semiconductor chip is stacked on a semiconductor chip where solder bumps are formed on electrodes, temporarily bonded by pressing, then heated in a reflow furnace, self-alignment is performed by surface tension and interfacial tension when the solder becomes liquid, and then the temperature is lowered to solidify the solder to stack and bond the semiconductor chips (see Patent Document 1, for example). In the method, after the solder is solidified, resin is filled into the gap between the semiconductor chips to seal and form a stacked electronic component.

### PRIOR ART DOCUMENT(S)

### Patent Document(s)

Patent Document 1: Japanese Laid-open No. 2009-110995

### SUMMARY OF INVENTION

### Technical Problem

However, in the conventional technology described in Patent Document 1, although it is possible to perform self-alignment of the stacked semiconductor chips by using molten solder, the process is complex as it requires filling resin into the gap after the solder is solidified, and there is room for improvement.

Therefore, the invention aims to perform alignment and bonding of stacking semiconductor chips by adopting a simple method.

### Solution to Problem

An alignment method according to an aspect of the invention is provided for a first semiconductor chip and a second semiconductor chip to be stacked. The alignment method includes: ultrasonically vibrating the first semiconductor chip; and bringing close a lower surface of the second semiconductor chip to an upper surface of the first semiconductor chip, so as to overlap with the first semiconductor chip that is ultrasonically vibrating, releasing the second semiconductor chip, and self-aligning the second semiconductor chip on the first semiconductor chip

In this way, by ultrasonically vibrating the semiconductor chip on the lower side, the semiconductor chip on the upper side can be self-aligned on the semiconductor chip on the lower side. Accordingly, it is possible to enable self-alignment by a simple method.

In the alignment method according to the invention, it may also be that the first semiconductor chip and the second semiconductor chip have identical external shapes

Accordingly, it is possible to improve the accuracy of self-alignment.

In the alignment method according to the invention, it may also be that in the ultrasonic vibrating, the first semiconductor chips mounted on a wafer or a substrate are ultrasonically vibrated through ultrasonically vibrating the wafer or the substrate, and in the self-aligning, an operation of bringing the lower surface of one of the second semiconductor chips close to the upper surface of one of the first semiconductor chips, so as to overlap with the one of the first semiconductor chips that is ultrasonically vibrating, and releasing the one of the second semiconductor chips is repetitively executed for each of the first semiconductor chips, and the second semiconductor chips are self-aligned on the first semiconductor chips.

Accordingly, it is possible to carry out self-alignment of multiple second semiconductor chips on multiple first semiconductor chips at the same time. Additionally, since the ultrasonic vibration is not stopped during the period until the second semiconductor chips are self-aligned on the respective first semiconductor chips, it is possible to suppress the adhesion of foreign matters on the first semiconductor chips on which the second semiconductor chips do not float, and the bonding quality can be improved.

A bonding method according to another aspect of the invention. The bonding method is provided for stacking and bonding a second semiconductor chip on a first semiconductor chip. The bonding method includes: an ultrasonic vibrating step of ultrasonically vibrating the first semiconductor chip; a self-aligning step of bringing close a lower surface of the second semiconductor chip to an upper surface of the first semiconductor chip, so as to overlap with the first semiconductor chip that is ultrasonically vibrating, releasing the second semiconductor chip, and self-aligning the second semiconductor chip on the first semiconductor chip; and a bonding step of reducing ultrasonic vibration of the first semiconductor chip until the lower surface of the second semiconductor chip contacts the upper surface of the first semiconductor chip, and stacking and bonding the second semiconductor chip to the first semiconductor chip.

Accordingly, the semiconductor chips can be stacked and bonded by a simple method.

In the bonding method according to the invention, it may also be that the first semiconductor chip and the second semiconductor chip have identical external shapes

Accordingly, it is possible to improve the accuracy of self-alignment.

In the bonding method according to the invention, it may also be that in the ultrasonic vibrating step, the first semiconductor chips mounted on a wafer or a substrate are ultrasonically vibrated through ultrasonically vibrating the wafer or the substrate, in the self-aligning step, an operation of bringing the lower surface of one of the second semiconductor chips close to the upper surface of one of the first semiconductor chips, so as to overlap with the one of the first semiconductor chips that is ultrasonically vibrating, and releasing the one of the second semiconductor chips is repetitively executed for each of the first semiconductor chips, and the second semiconductor chips are self-aligned on the first semiconductor chips, and in the bonding step, ultrasonic vibration of the wafer or the substrate is reduced until the respective lower surfaces of the respective second semiconductor chips contact the respective upper surfaces of the respective first semiconductor chips, and the respective second semiconductor chips are stacked and bonded to the respective first semiconductor chips.

Accordingly, it is possible to carry out self-alignment of multiple second semiconductor chips on multiple first semiconductor chips at the same time while performing self-alignment at the same time. Additionally, since the ultrasonic vibration is not stopped during the period until the second semiconductor chips are self-aligned on the respective first semiconductor chips, it is possible to suppress the adhesion of foreign matters on the first semiconductor chips on which the second semiconductor chips do not float, and the bonding quality can be improved.

The bonding method according to the invention may also include: a first hydrophilization step of hydrophilizing the upper surface of the first semiconductor chip; and a second hydrophilization step of hydrophilizing the lower surface of the second semiconductor chip. The bonding method includes: a hydrophilic bonding step of bonding by bringing the lower surface of the second semiconductor chip that is hydrophilized into contact with the upper surface of the first semiconductor chip that is hydrophilized; and a thermal diffusion bonding step of thermal diffusion bonding an electrode of the first semiconductor chip and an electrode of the second semiconductor chip by heating the first semiconductor chip and the second semiconductor chip that are hydrophilically bonded.

In this way, by bonding the surfaces of the semiconductor chips together through hydrophilic bonding and bonding each electrode through thermal diffusion bonding, stacked bonding of semiconductor chips can be performed by a simple method.

The bonding method according to the invention may also include: a third hydrophilization step of hydrophilizing each of the upper surfaces of the first semiconductor chips mounted on the wafer or the substrate; and a fourth hydrophilization step of hydrophilizing each of the lower surfaces of the second semiconductor chips, The bonding method includes: a hydrophilic bonding step of bonding by bringing the respective lower surfaces of the respective second semiconductor chips that are hydrophilized into contact with the respective upper surfaces of the respective first semiconductor chips that are hydrophilized; and a thermal diffusion bonding step of thermal diffusion bonding each electrode of each of the first semiconductor chips and each electrode of each of the second semiconductor chips by heating each of the first semiconductor chips and each of the second semiconductor chips that are hydrophilically bonded together with the wafer or the substrate.

Accordingly, multiple semiconductor chips can be hydrophilically bonded at the same time, while the respective electrodes can be thermal diffusion bonded at the same time.

The bonding method according to the invention may also include: a first activation step of activating the upper surface of the first semiconductor chip; and a second activation step of activating the lower surface of the second semiconductor chip.

In the bonding step, the lower surface of the second semiconductor chip that is activated may be bonded to the upper surface of the first semiconductor chip that is activated through surface activation bonding.

Accordingly, the semiconductor chips can be stacked and bonded by surface activation bonding.

An electronic component manufacturing device according to an embodiment of the invention is provided for stacking and bonding a second semiconductor chip to a first semiconductor chip. The electronic component manufacturing device includes: a stage, provided for adsorption-fixing the first semiconductor chip to an adsorption surface on an upper side; a collet, provided for holding and releasing the second semiconductor chip; a bonding head, provided for moving the collet in a direction along the adsorption surface of the stage and a direction of approaching and departing from the adsorption surface; an ultrasonic vibrator, provided for ultrasonically vibrating the stage; and a control part, provided for adjusting an operation among the collet, the bonding head, and the ultrasonic vibrator. The control part includes a processor for performing information processing. The processor is configured for: ultrasonically vibrating the first semiconductor chip by ultrasonically vibrating the stage by using the ultrasonic vibrator; moving the collet holding the second semiconductor chip to a position overlapping with the first semiconductor chip by using the bonding head and lowering the collet until a lower surface of the second semiconductor chip is close to an upper surface of the first semiconductor chip; releasing the second semiconductor chip from the collet and self-aligning the second semiconductor chip onto the first semiconductor chip; and reducing an output of the ultrasonic vibrator and bringing the lower surface of the second semiconductor chip into contact with the upper surface of the first semiconductor chip, and stacking and bonding the second semiconductor chip to the first semiconductor chip.

In the electronic component manufacturing device according to the invention, it may also be that the first semiconductor chip and the second semiconductor chip have identical external shapes

In the electronic component manufacturing device according to the invention, it may also be that the stage is provided for adsorption-fixing a wafer or a substrate on which the first semiconductor chips are mounted, and the processor of the control part is configured for: ultrasonically vibrating the first semiconductor chips mounted on the wafer or the substrate by ultrasonically vibrating the stage by using the ultrasonic vibrator, repetitively executing an operation of moving the collet holding one of the second semiconductor chips to a position overlapping with one of the first semiconductor chips, lowering the collet until the collet is close to the upper surface of the one of the first semiconductor chips, and releasing the one of the second semiconductor chips from the collet, and self-aligning the second semiconductor chips onto the first semiconductor chips, and reducing an output of the ultrasonic vibrator and bringing the respective lower surfaces of the respective second semiconductor chips into contact with the respective upper surface of the respective first semiconductor chips, and stacking and bonding the respective second semiconductor chips to the respective first semiconductor chips.

An electronic component manufacturing system may include the electronic component manufacturing device. The electronic component manufacturing system may further include: a hydrophilization device; and a heating device. The hydrophilization device may hydrophilize the upper surface of the first semiconductor chip and the lower surface of the second semiconductor chip and supply the first semiconductor chip and the second semiconductor chip to the electronic component manufacturing device. The processor of the electronic component manufacturing device may reduce an output of the ultrasonic vibrator to bring the lower surface that is hydrophilized in the second semiconductor chip into contact with the upper surface that is hydrophilized in the first semiconductor chip, and may hydrophically bond the first semiconductor chip and the second semiconductor chip. The heating device may heat a bonded body in which the second semiconductor chip is hydrophilically bonded to the first semiconductor chip and thermal diffusion bond an electrode of the first semiconductor chip and an electrode of the second semiconductor chip

Accordingly, an electronic component in which a semiconductor chip is stacked can be efficiently manufactured.

An electronic component manufacturing system may include the electronic component manufacturing device. The electronic component manufacturing system may further include: a hydrophilization device; and a heating device. The hydrophilization device my hydrophilize the respective upper surfaces of the respective first semiconductor chips and the respective lower surfaces of the respective second semiconductor chip and supply the first semiconductor chips and the second semiconductor chips to the electronic component manufacturing device. the processor of the electronic component manufacturing device may reduce an output of the ultrasonic vibrator to bring the respective lower surfaces that are hydrophilized in the respective second semiconductor chips into contact with the respective upper surfaces that are hydrophilized in the respective first semiconductor chips, and may hydrophically bond the respective first semiconductor chips and the respective second semiconductor chips. The heating device may heat a bonded body in which each of the second semiconductor chips is hydrophilically bonded to each of the first semiconductor chips and thermal diffusion bond each electrode of each of the first semiconductor chips and each electrode of each of the second semiconductor chips

Accordingly, an electronic component in which a semiconductor chip is stacked can be efficiently manufactured.

### Effects of Invention

According to the invention, alignment and bonding of stacking semiconductor chips can be performed by a simple method.

### BRIEF DESCRIPTION OF DRAWINGS

FIG. 1 is a system diagram showing a schematic configuration of an electronic component manufacturing system according to an embodiment.

FIG. 2 is a system diagram showing a configuration of a bonding apparatus according to an embodiment.

FIG. 3 is a flowchart showing an operation of the electronic component manufacturing system shown in FIG. 1.

FIG. 4 is an explanatory diagram showing a process of transporting a wafer to which a first semiconductor chip is attached and a second semiconductor chip into the bonding apparatus shown in FIG. 2.

FIG. 5 is an explanatory diagram showing a process of picking up the second semiconductor chip and positioning the second semiconductor chip over the first semiconductor chip in the bonding apparatus shown in FIG. 2.

FIG. 6 is an explanatory diagram showing a state where ultrasonic vibration is started in a state where the second semiconductor chip is positioned over the first semiconductor chip, and a collet is lowered to bring the second semiconductor chip close to the first semiconductor chip.

FIG. 7 is an explanatory diagram showing self-alignment of the second semiconductor chip.

FIG. 8 is a detailed cross-sectional view of a portion A shown in FIG. 7.

FIG. 9 is a diagram showing hydrophilic bonding of the second semiconductor chip.

FIG. 10 is a detailed cross-sectional view of a portion B shown in FIG. 8.

FIG. 11 is an explanatory diagram showing self-alignment of a second second semiconductor chip.

FIG. 12 is an explanatory diagram showing an intermediate product after the hydrophilic bonding of all the second semiconductor chips has been completed.

FIG. 13 is an explanatory diagram showing a discharge process of transporting the intermediate product to a hydrophilization device.

FIG. 14 is an explanatory diagram showing a thermal diffusion bonding process of an electronic component in which a predetermined number of stages of second semiconductor chips are stacked.

FIG. 15 is a flowchart showing another operation of the electronic component manufacturing system shown in FIG. 1.

FIG. 16 is an explanatory diagram showing self-alignment in the bonding apparatus shown in FIG. 2 during the operation shown in FIG. 15.

FIG. 17 is an explanatory diagram showing hydrophilic bonding in the bonding apparatus shown in FIG. 2 during the operation shown in FIG. 15.

FIG. 18 is a system diagram showing a schematic configuration of an electronic component manufacturing system of another embodiment.

### DESCRIPTION OF EMBODIMENTS

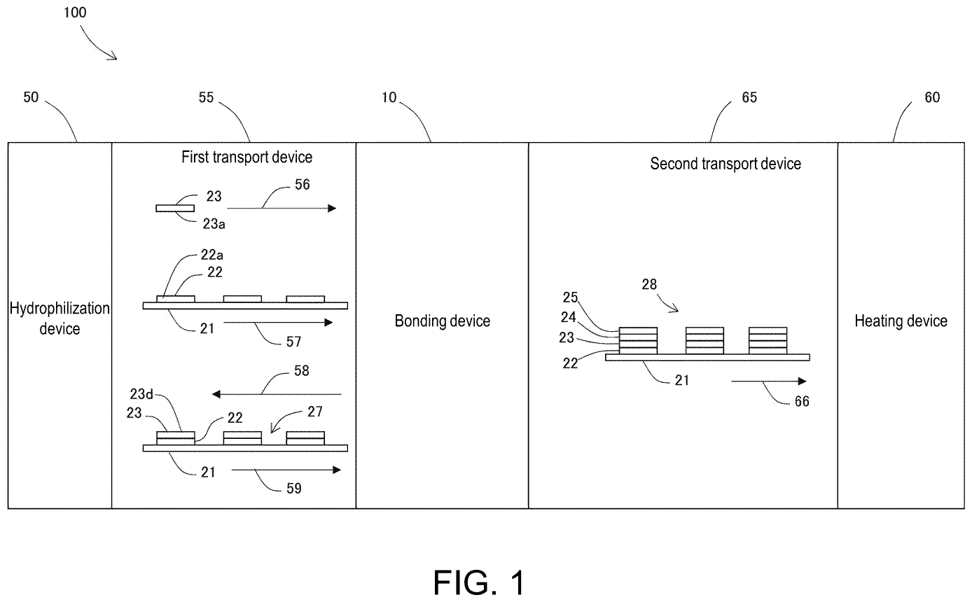

The following describes an electronic component manufacturing system 100 of an embodiment. As shown in FIG. 1, the electronic component manufacturing system 100 includes a bonding apparatus 10 which is an electronic component manufacturing device, a hydrophilization device 50, a heating device 60, a first transport device 55, and a second transport device 65.

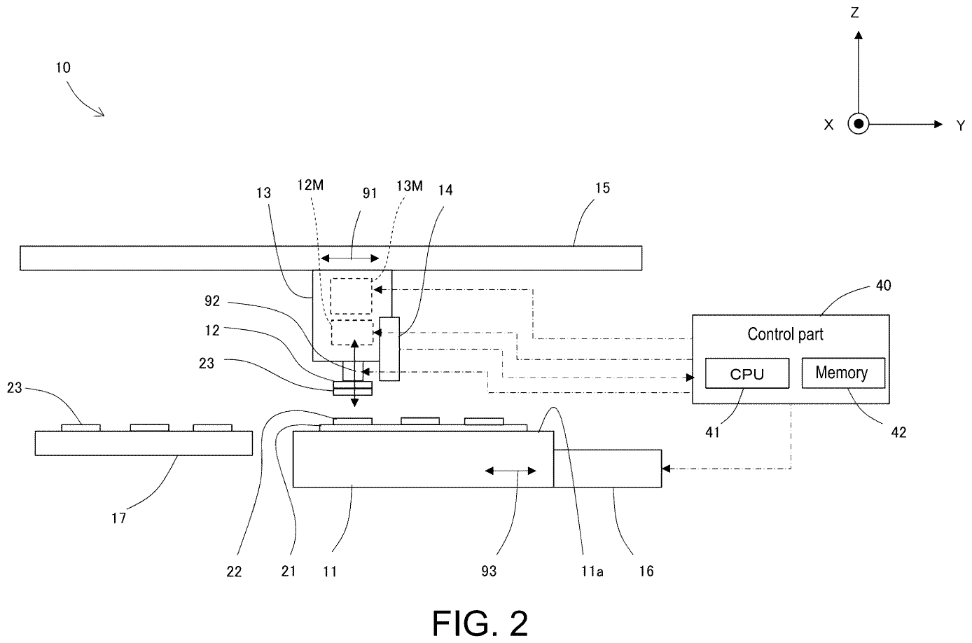

The bonding apparatus 10 performs stacked bonding of a second semiconductor chip 23 on a first semiconductor chip 22. Details of the bonding apparatus 10 will be described later with reference to FIG. 2. In this embodiment, the first semiconductor chip 22 and the second semiconductor chip 23 have identical external shapes.

The hydrophilization device 50 hydrophilizes an upper surface 22a of the first semiconductor chip 22 and a lower surface 23a of the second semiconductor chip 23. Various configurations can be considered for the hydrophilization device 50. For example, it may be configured to hydrophilize the upper surface 22a of the first semiconductor chip 22 and the lower surface 23a of the second semiconductor chip 23 by irradiating atmospheric pressure plasma. Additionally, the upper surface 22a and the lower surface 23a may be cleaned with pure water, etc., and after cleaning, the upper surface 22a and the lower surface 23a may be hydrophilized by using atmospheric pressure plasma.

The first transport device 55, as shown by an arrow 56 in FIG. 1, transports the second semiconductor chip 23 in which the lower surface 23a is hydrophilized into the bonding apparatus 10. Additionally, the first transport device 55, as shown by an arrow 57 in FIG. 1, transports a wafer 21 on which the first semiconductor chip 22 in which the upper surface 22a is hydrophilized is mounted to the bonding apparatus 10. Furthermore, the first transport device 55, as shown by an arrow 58 in FIG. 1, transports the intermediate product 27, in which the second semiconductor chip 23 is bonded on the first semiconductor chip 22 in the bonding apparatus 10, to the hydrophilization device 50, and, as shown by an arrow 59 in FIG. 1, transports the intermediate product 27 in which the upper surface 23d of the second semiconductor chip 23 is hydrophilized by the hydrophilization device 50 into the bonding apparatus 10.

The second transport device 65, as shown by an arrow 66 in FIG. 1, transports the electronic component 28, which is a bonded body in which a predetermined number of stages of second semiconductor chips 23 to 25 are stacked by the bonding apparatus 10, to the heating device 60. The heating device 60 heats the transported electronic component 28 to perform thermal diffusion bonding of each electrode of the first semiconductor chip 22 and each electrode of each of the second semiconductor chips 23 to 25.

Next, the structure of the bonding apparatus 10 will be described with reference to FIG. 2. As shown in FIG. 2, the bonding apparatus 10 includes a stage 11, a collet 12, a bonding head 13, a camera 14, a guide rail 15, an ultrasonic vibrator 16, a loading stand 17, and a control part 40. In the following description, the direction in which the guide rail 15 extends is referred to as Y-direction, the direction perpendicular to Y-direction in the horizontal plane is referred to as X-direction, and the upper-lower direction is referred to as the Z-direction. Additionally, the side of the loading stand 17 is described as the negative side of Y-direction, the side of the stage 11 as the positive side of Y-direction, the front side of the paper surface in FIG. 1 as the positive side of X-direction, the far side of the paper surface as the negative side of X-direction, the upward direction as the positive side of Z-direction, and the downward direction as the negative side of Z-direction.

The stage 11 vacuum adsorbs the first semiconductor chip 22 by vacuum adsorbing the first semiconductor chip 22, or the wafer 21 on which multiple first semiconductor chips 22 are mounted, on an adsorption surface 11a the upper side.

The collet 12 is connected to the lower end of the bonding head 13, and adsorbs the second semiconductor chip 23 to the tip to hold the second semiconductor chip 23, and release the second semiconductor chip 23.

The bonding head 13 includes a Y-direction drive motor 13M inside, and moves in Y-direction as shown by an arrow 91 in FIG. 2, by being guided by the guide rail 15. Additionally, the bonding head 13 incorporates a Z-direction drive motor 12M that moves the collet 12 in Z-direction as shown by an arrow 92 in FIG. 2. Furthermore, the guide rail 15 moves in X-direction by an X-direction drive device (not shown). Therefore, the bonding head 13 and the X-direction drive device (not shown) move the collet 12 in X-Y direction along the adsorption surface 11a of the stage 11, and in Z-direction which is a direction of approaching and departing from the adsorption surface 11a.

The camera 14 is attached to the bonding head 13, and acquires an image of the first semiconductor chip 22 adsorbed on the adsorption surface 11a of the stage 11, or the second semiconductor chip 23 loaded on the loading stand 17.

The ultrasonic vibrator 16 includes an ultrasonic vibration element inside, and is connected to the stage 11 and ultrasonically vibrate the stage 11.

The loading stand 17 is a stand on which the second semiconductor chip 23, whose lower surface 23a is hydrophilized by a hydrophilization device 50, is temporarily loaded. The loading stand 17 may, for example, be configured to allow the second semiconductor chip 23 to be loaded on the upper surface in a contactless manner through ultrasonic vibration or air pressure.

The control part 40 is a computer that includes a CPU 41, which is a processor that performs information processing, and a memory 42 that stores operation programs and control data. The image data acquired by the camera 14 is input to the control part 40. The control part 40 detects the positions of the first semiconductor chip 22 and the second semiconductor chip 23 by performing an image analysis of the input image data. Additionally, the Z-direction drive motor 12M installed inside the bonding head 13 detects the Z-direction position of the collet 12 and outputs the Z-direction position to the control part 40.

The Y-direction drive motor 13M of the bonding head 13, the Z-direction drive motor 12M, the X-direction drive device, the collet 12, and the ultrasonic vibrator 16 operate according to the commands from the control part 40. The Y-direction drive motor 13M, the Z-direction drive motor 12M, and the X-direction drive device adjust the XYZ position of the collet 12 based on the commands from the control part 40. Additionally, the collet 12 performs adsorption-hold and release of the second semiconductor chip 23 according to the commands from the control part 40. The ultrasonic vibrator 16 performs ultrasonic vibration of the stage 11 based on the commands from the control part 40.

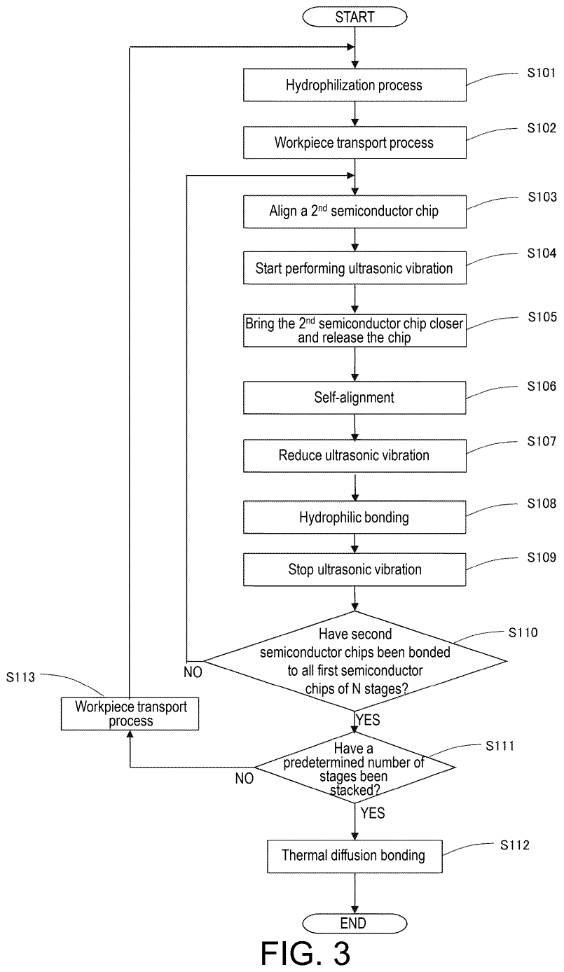

Next, referring to FIGS. 3 to 14, the operation of the electronic component manufacturing system 100 of the embodiment will be described. In the following description, the wafer 21 loaded with three first semiconductor chips 22 is vacuum-adsorbed to the adsorption surface 11a of the stage 11, and the operation of bonding the second semiconductor chip 23 onto each of the first semiconductor chips 22 will be described. In the case of distinguishing between the three first semiconductor chips 22, the three first semiconductor chips 22 will be denoted as first semiconductor chips 221, 222, and 223. Also, in the case of distinguishing between the three second semiconductor chips 23, the three second semiconductor chips 23 will be denoted as second semiconductor chips 231, 232, and 233. The first semiconductor chips 221, 222, 223 and the second semiconductor chips 231, 232, 233 have identical external shapes respectively. The number of the first semiconductor chips 22 loaded on the wafer 21 is not limited to three, and may be more than three or may be just one.

First, the wafer 21 loaded with multiple first semiconductor chips 22 for manufacturing the electronic component 28 (see FIG. 1) and multiple second semiconductor chips 23 are transported to the hydrophilization device 50. The hydrophilization device 50 executes a hydrophilization process as shown in Step S101 in FIG. 3. In the hydrophilization process, the upper surface 22a of the first semiconductor chip 22 and the lower surface 23a of the second semiconductor chip 23 are hydrophilized by irradiating atmospheric pressure plasma. After the hydrophilization process is completed, as shown in Step S102 in FIG. 3, the first transport device 55 executes a workpiece transport process to transport the wafer 21 loaded with the first semiconductor chips 22 for which the hydrophilic process is completed and the second semiconductor chips 23 to the bonding apparatus 10.

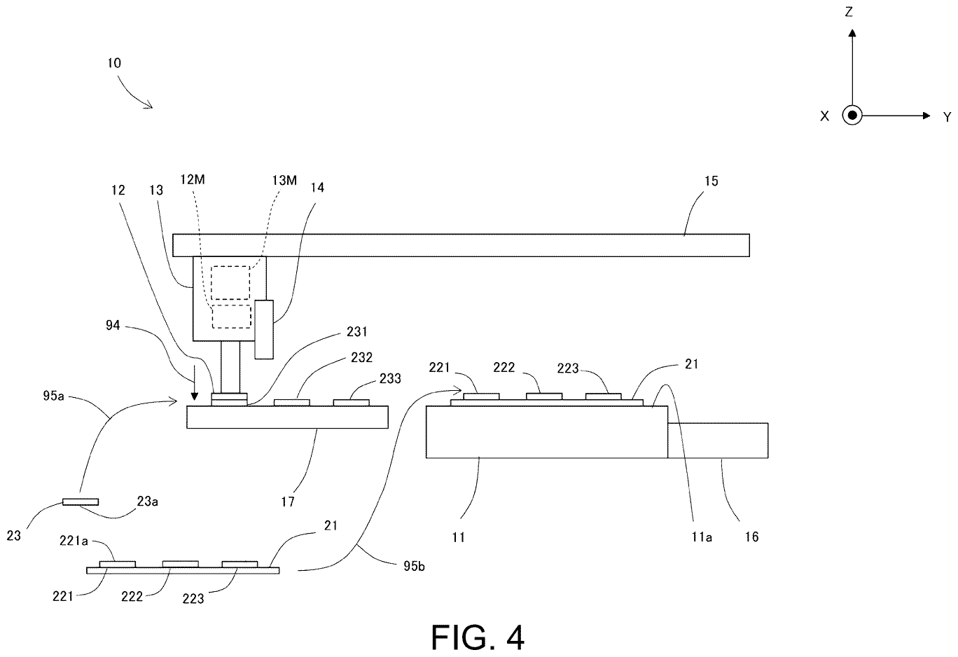

As shown by an arrow 95a in FIG. 4, the first transport device 55, in the workpiece transport process, transports the second semiconductor chip 23 whose lower surface 23a is hydrophilized to the loading stand 17 inside the bonding apparatus 10. Also, as shown by an arrow 95b in FIG. 4, the first transport device 55, in the workpiece transport process, transports the wafer 21 loaded with the first semiconductor chips 22 whose hydrophilic process is completed to the vicinity of the adsorption surface 11a of the stage 11. The transported wafer 21 is conveyed onto the adsorption surface 11a of the stage 11 by a feeding device (not shown), and is adsorption-fixed to a predetermined position on the adsorption surface 11a.

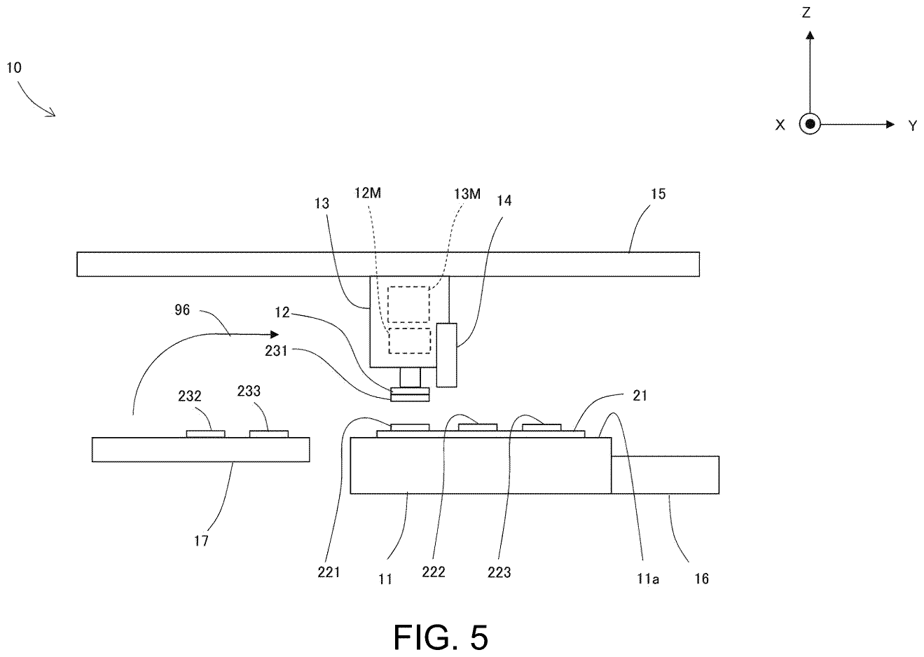

After the first semiconductor chip 22 and the second semiconductor chip 23 are transported to the predetermined positions, the CPU 41 of the control part 40 of the bonding apparatus 10 executes the pickup of the second semiconductor chip 23 in Step S103 of FIG. 3. As shown in FIG. 4, the CPU 41 moves the bonding head 13 in the X-Y direction by using the Y-direction drive motor 13M and the X-direction drive device, and moves the collet 12 above the first second semiconductor chip 231 loaded on the loading stand 17. Then, the CPU 41 lowers the collet 12 as shown by an arrow 94 in FIG. 4 by using the Z-direction drive motor 12M, and adsorption-grips the second semiconductor chip 231 at the tip of the collet 12. Then the CPU 41, as shown by an arrow 96 in FIG. 5, raises the collet 12 by using the Z-direction drive motor 12M to pick up the second semiconductor chip 231.

Next, the CPU 41 executes the positioning of the second semiconductor chip 231 as shown in Step S103 of FIG. 3. The CPU 41 moves the bonding head 13 toward the positive side in Y-direction as shown by an arrow 96 in FIG. 5 by using the Y-direction drive motor 13M. Then, the CPU 41 detects the position of the first semiconductor chip 221 based on the image of the first first semiconductor chip 221 captured by the camera 14. Then, the CPU 41 moves the bonding head 13 by using the Y-direction drive motor 13M and the X-direction drive device so that the position of the second semiconductor chip 231 overlaps with the position of the first semiconductor chip 221, thereby performing the positioning of the second semiconductor chip 231.

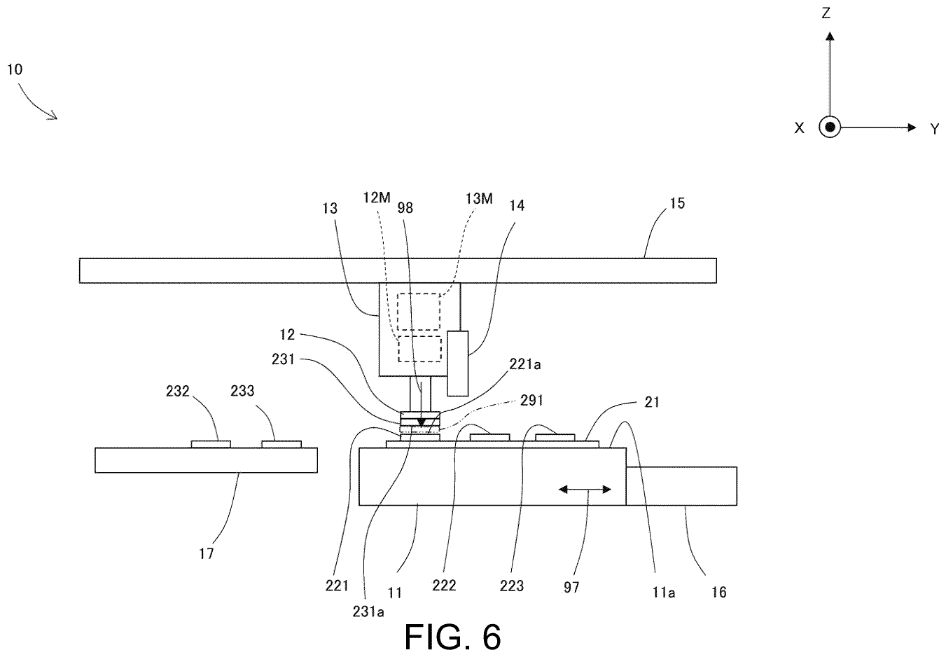

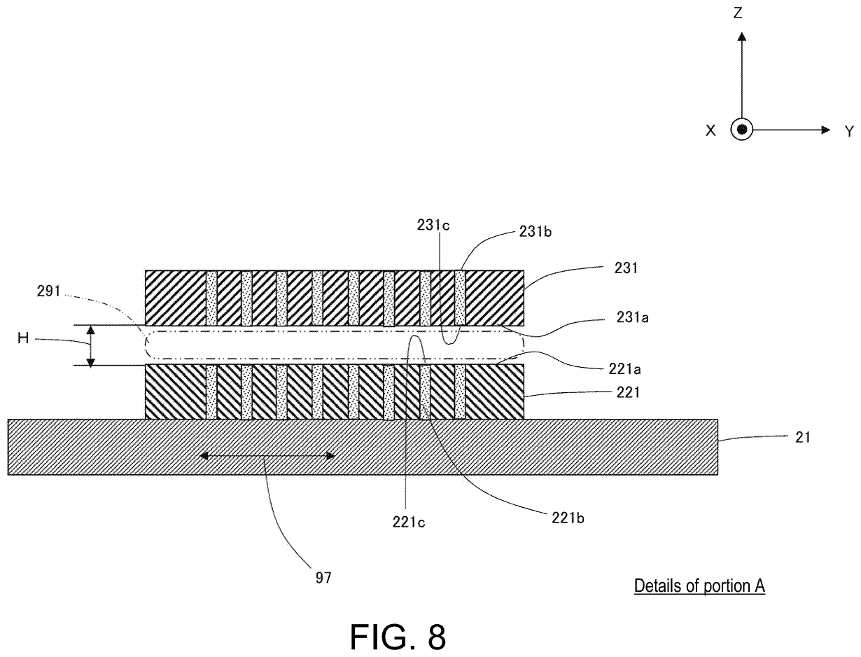

Next, the CPU 41 proceeds to Step S104 in FIG. 3, drives the ultrasonic vibrator 16, and starts the ultrasonic vibration of the stage 11 as shown by an arrow 97 in FIG. 6. Then, the CPU 41 proceeds to Step S105 in FIG. 3, operates the Z-direction drive motor 12M, and brings the lower surface 231a of the second semiconductor chip 231 close to the upper surface 221a of the first semiconductor chip 221 as shown by an arrow 98 in FIG. 6. In this way, in the state where the first semiconductor chip 221 is ultrasonically vibrated, if the second semiconductor chip 231 is brought close, an ultrasonic squeeze effect between the upper surface 221a of the first semiconductor chip 221 and the lower surface 231a of the second semiconductor chip 231 occurs. The ultrasonic squeeze effect is an effect where, if one of two flat plates facing each other through a minute gap is vibrated, a pressure higher than the outside is generated within the gap due to the influence of viscosity. When the ultrasonic squeeze effect occurs, an ultrasonic squeeze air film 291 that prevents the contact between the upper surface 221a of the first semiconductor chip 221 and the lower surface 231a of the second semiconductor chip 231 is formed, and a holding force that holds the lower surface 231a of the second semiconductor chip 231 on the upper surface 211a of the first semiconductor chip 221 is generated. Here, the close distance between the lower surface 231a of the second semiconductor chip 231 and the upper surface 221a of the first semiconductor chip 221 may be slightly larger than the thickness H of the ultrasonic squeeze air film 291 (see FIG. 8). The thickness H of the ultrasonic squeeze air film 291 varies depending on the amplitude of the ultrasonic vibration. However, for example, in the case where the thickness H of the ultrasonic squeeze air film 291 is several μm to 10 μm, the close distance may be about 10 μm to 20 μm.

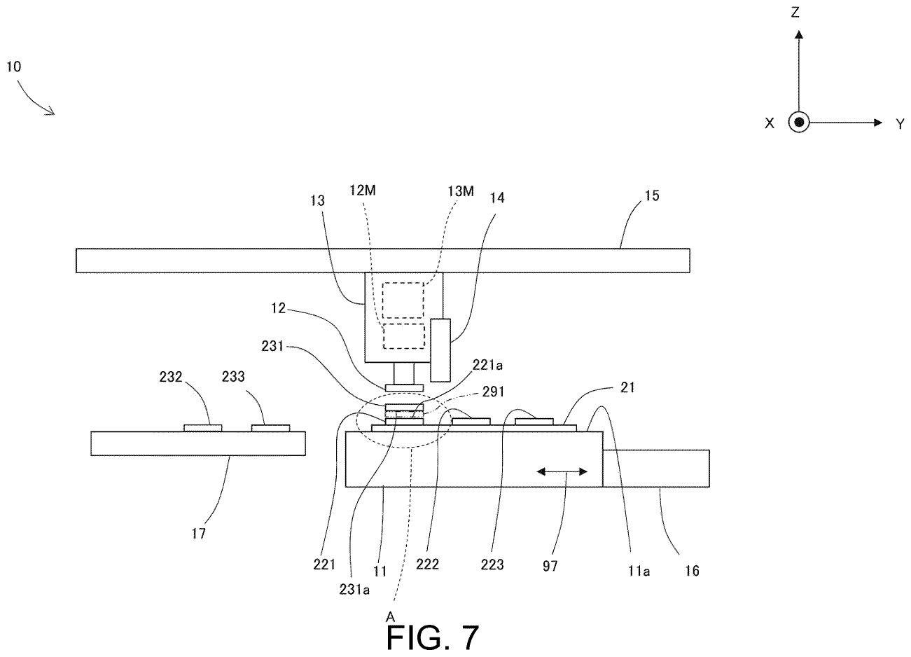

Next, the CPU 41 causes the collet 12 to perform a release operation as shown in Step S105 in FIG. 3, and proceeds to Step S106 in FIG. 3 to perform self-alignment. When the second semiconductor chip 231 is released from the collet 12, as shown in FIG. 7 and FIG. 8, the second semiconductor chip 231 is separated from the tip of the collet 12 and is held in a state of floating above the upper surface 221a of the first semiconductor chip 221 by using the ultrasonic squeeze air film 291. The holding force generated by the ultrasonic squeeze effect occurs in both a direction perpendicular to the upper surface 221a of the first semiconductor chip 221 and a direction parallel thereto (i.e., the surface direction). That is, in the case where the ultrasonic squeeze effect occurs, a force acts on the second semiconductor chip 231 in the direction of floating from the upper surface 221a of the first semiconductor chip 221. Also, in the case where the ultrasonic squeeze effect occurs, the second semiconductor chip 231 tends to stay within the vibration surface. Therefore, even if the second semiconductor chip 231 is deviated temporarily in the surface direction due to external force, the second semiconductor chip 231 moves in the surface direction so that the entirety of the second semiconductor chip 231 is positioned within the vibration surface, and tends to return to a state where the second semiconductor chip 231 faces the upper surface 221a of the first semiconductor chip 221.

Here, in the embodiment, since the external shape of the first semiconductor chip 221 and the external shape of the second semiconductor chip 231 are identical, through the ultrasonic squeeze effect, the second semiconductor chip 231 automatically moves in the surface direction so that the entirety of the second semiconductor chip 231 is positioned within the vibration surface (i.e., within the area on the inner side with respect to the external shape of the upper surface 221a of the first semiconductor chip 221). As a result, the second semiconductor chip 231 is self-aligned in the surface direction. Then, as shown in FIG. 8, the position of each electrode 231b of the second semiconductor chip 231 and the positions of the electrodes 221b of the first semiconductor chip 221 become aligned.

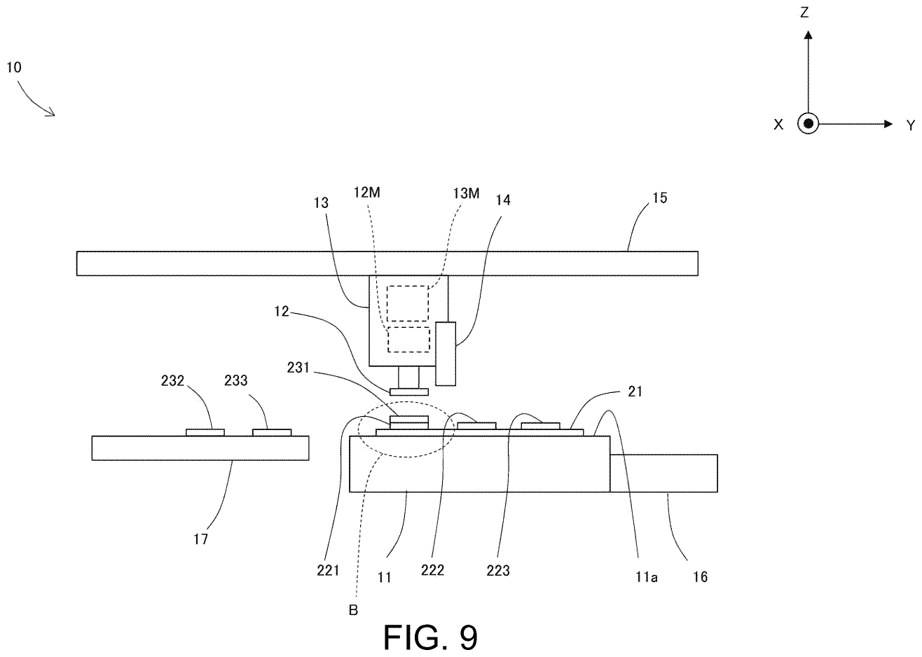

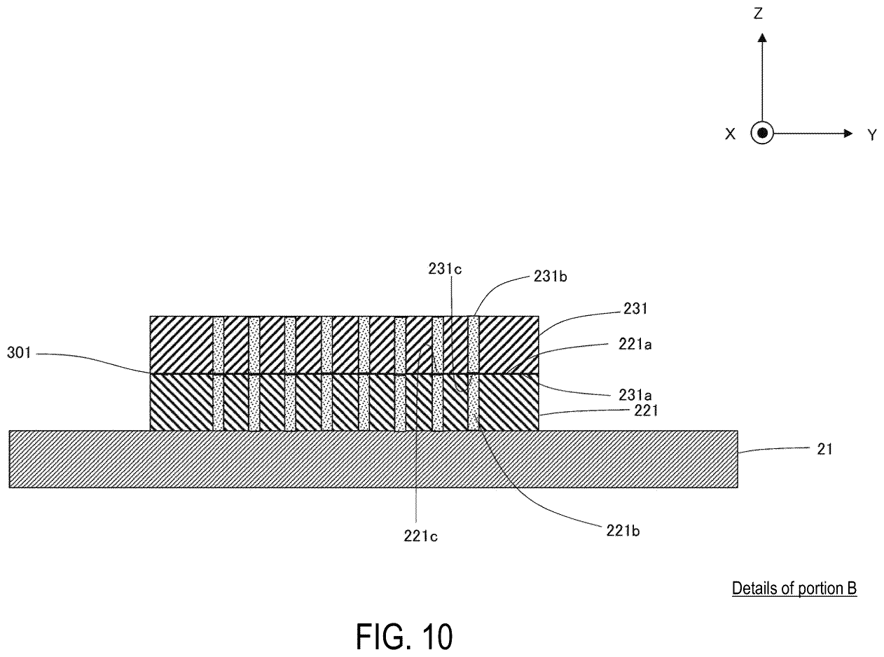

Next, the CPU 41 gradually reduces the amplitude of the ultrasonic vibration of the stage 11 by the ultrasonic vibrator 16 as shown in Step S107 in FIG. 3. Then, the thickness H of the ultrasonic squeeze air film 291 shown in FIG. 8 gradually decreases. And when the CPU 41 reduces the amplitude of the ultrasonic vibration to a certain extent, as shown in FIG. 9 and FIG. 10, the second semiconductor chip 231 falls onto the first semiconductor chip 221 due to gravity, and the lower surface 231a of the second semiconductor chip 231 contacts the upper surface 221a of the first semiconductor chip 221. Since the lower surface 231a of the second semiconductor chip 231 and the upper surface 221a of the first semiconductor chip 221 have been hydrophilized by the hydrophilization device 50, when the lower surface 231a contacts the upper surface 221a, as shown in Step S108 in FIG. 3, the lower surface 231a of the second semiconductor chip 231 and the upper surface 221a of the first semiconductor chip 221 are hydrophilically bonded at a junction surface 301.

The CPU 41 proceeds to Step S109 in FIG. 3 and stops the ultrasonic vibration of the stage 11 by the ultrasonic vibrator 16.

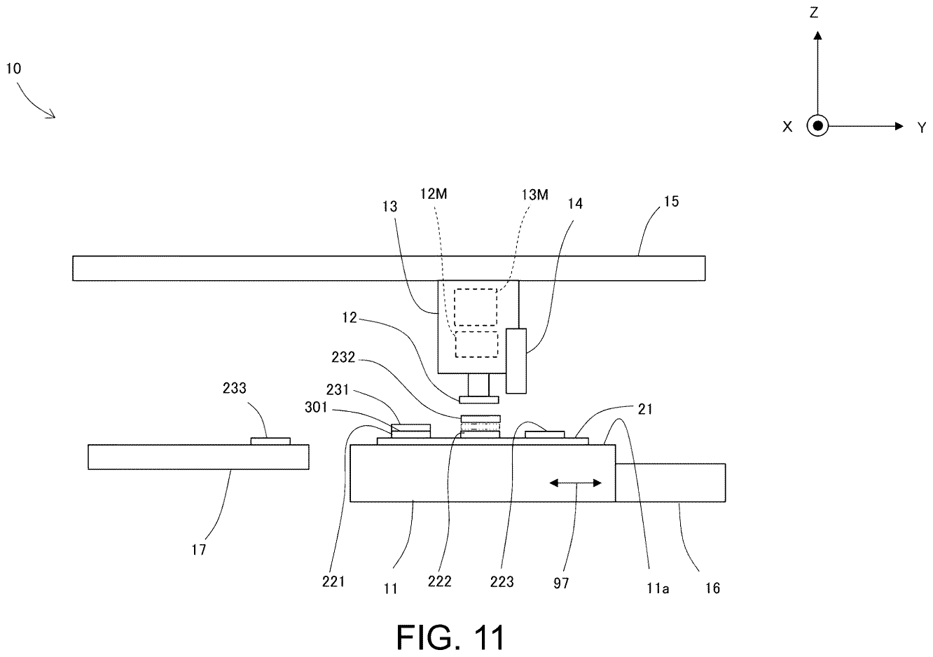

The CPU 41 determines in Step S110 of FIG. 3 whether all the second semiconductor chips 23 are bonded to all the first semiconductor chips 22 in certain stages (N stages). And if the CPU 41 determines NO in Step S110 of FIG. 3, the CPU 41 returns to Step S103 of FIG. 3, and as shown in FIG. 11, picks up and positions the second second semiconductor chip 232, performs self-alignment through ultrasonic vibration, and bonds the second second semiconductor chip 232 onto the second first semiconductor chip 222. The CPU 41 repeatedly executes Steps S103 to S109 of FIG. 3 until the CPU 41 determines YES in Step S110 of FIG. 3.

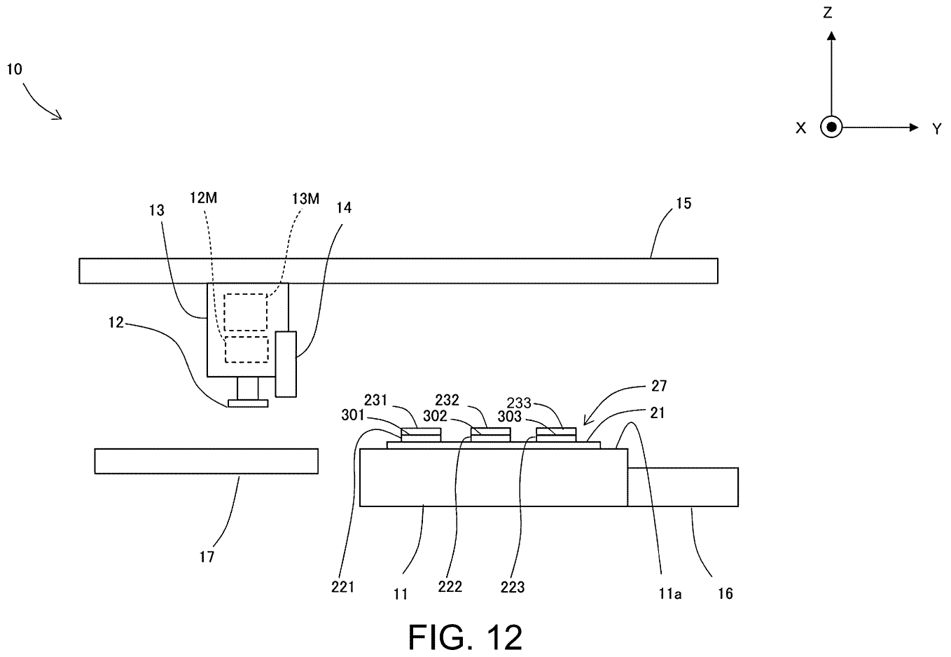

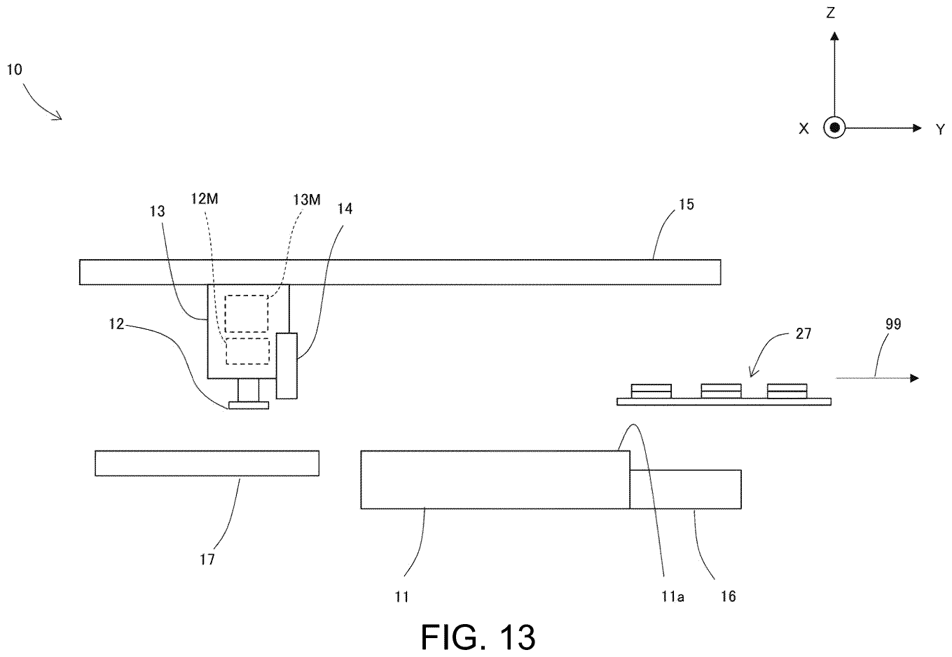

In addition, as shown in FIG. 12, after bonding the three second semiconductor chips 231 to 233 onto the three first semiconductor chips 221 to 223 to create the intermediate product 27, the CPU determines YES in Step S110 of FIG. 3 and proceeds to Step S111 and determines whether a predetermined number of stages, such as three stages in the case of the electronic component 28 shown in FIG. 1, of the second semiconductor chips 23, 24, 25 are stacked. If determining NO in Step S111 of FIG. 3, the CPU 41 releases the adsorption of the intermediate product 27 to the stage 11 and outputs a start operation signal to the first transport device 55. As a result, the first transport device 55 transports the intermediate product 27 to the hydrophilization device 50 as shown by an arrow 99 in FIG. 13 (workpiece transport process). The hydrophilization device 50 returns to Step S101 of FIG. 3, performs a hydrophilic process on the upper surface 23d (see FIG. 1) of the second semiconductor chip 23 of the intermediate product 27, and in Step S102 of FIG. 3, transports the hydrophilized intermediate product 27 to the bonding apparatus 10. The bonding apparatus 10 executes the operations of Steps S103 to S110 of FIG. 3 to bond the second semiconductor chip 24 of the second stage onto the second semiconductor chip 23 of the first stage.

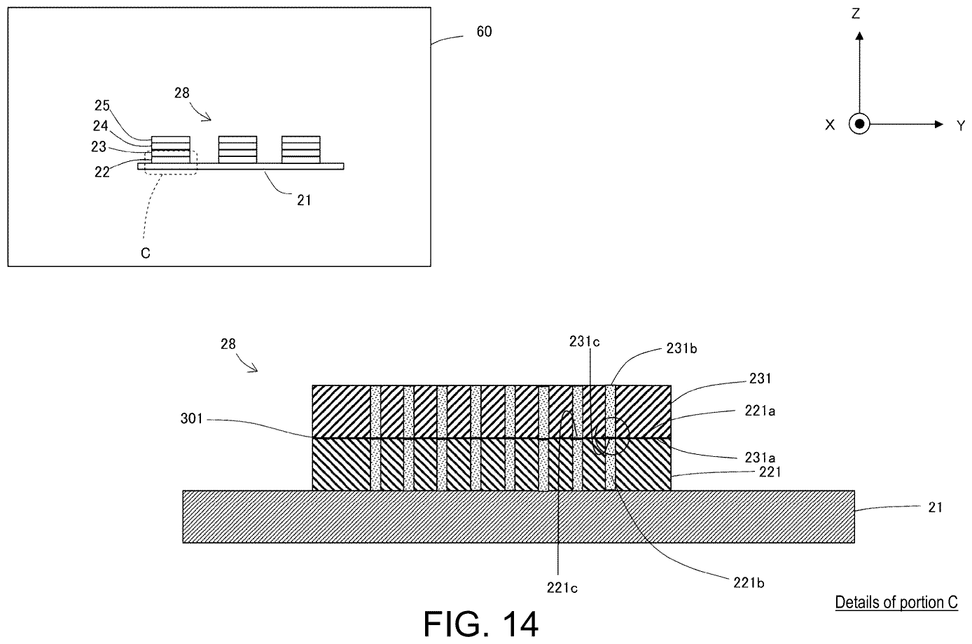

Thereafter, the bonding apparatus 10 and the hydrophilization device 50 repeatedly execute the operations of Steps S101 to S111, S113 of FIG. 3, and, as shown in FIG. 14, form the electronic component 28, which is a bonded body with the second semiconductor chips 23, 24, 25 of three stages stacked on the first semiconductor chip 22. When the electronic component 28 is formed, the CPU 41 determines YES in Step S111 of FIG. 3, releases the adsorption of the electronic component 28 on the stage 11, and outputs a start operation signal to the second transport device 65. As a result, the second transport device 65 transports the electronic component 28 to the heating device 60.

The heating device 60, in Step S112 of FIG. 3, heats the electronic component 28, and, as shown in detail in a portion C of FIG. 14, thermal diffusion bonds the upper end surface 221c of the electrode 221b of the first semiconductor chip 221 and the lower end surface 231c of the electrode 231b of the second semiconductor chip 231. When the thermal diffusion bonding is completed, the electronic component 28 becomes a finished product.

As described above, the bonding apparatus 10 of the embodiment can perform self-alignment of the second semiconductor chip 23 on the upper side onto the first semiconductor chip 22 by ultrasonically vibrating the first semiconductor chip 22 on the lower side, and can perform stacked bonding of the first semiconductor chip 22 and the second semiconductor chip 23 by a simple method.

The above describes the configuration and operation of the electronic component manufacturing system 100 and the bonding apparatus 10 of the embodiment, but the operations of Step S103 to Step S106 in FIG. 3 of the bonding apparatus 10 are a method for self-alignment of the second semiconductor chip 23 onto the first semiconductor chip 22. In addition, the operations of Step S103 to Step S109 in FIG. 3 of the bonding apparatus 10 are a bonding method for stacked bonding of the second semiconductor chip 23 onto the first semiconductor chip 22. Here, Step S104 in FIG. 3 is the ultrasonic vibration process of the bonding method, Step S105 and Step S106 in FIG. 3 are the self-alignment process of the bonding method, and Step S107 to Step S109 in FIG. 3 are the bonding process of the bonding method. Furthermore, Step S101 in FIG. 3 is the first hydrophilization process and the second hydrophilization process of the bonding method, Step S107 to Step S109 in FIG. 3 are the hydrophilic bonding process of the bonding method, and Step S112 in FIG. 3 is the thermal diffusion bonding process of the bonding method.

In the above description, the CPU 41 reduces the amplitude of the ultrasonic vibration of the stage 11 by the ultrasonic vibrator 16 in Step S107 of FIG. 3, brings the lower surface 231a of the second semiconductor chip 231 into contact with the upper surface 221a of the first semiconductor chip 221 by gravity in Step S108 of FIG. 3, and then stops the ultrasonic vibration of the stage 11 by using the ultrasonic vibrator 16 in Step S109 of FIG. 3. However, the invention is not limited thereto. For example, the lower surface 231a of the second semiconductor chip 231 may be brought into contact with the upper surface 221a of the first semiconductor chip 221 by stopping the ultrasonic vibration of the stage 11 by the ultrasonic vibrator 16 without reducing the amplitude of the ultrasonic vibration.

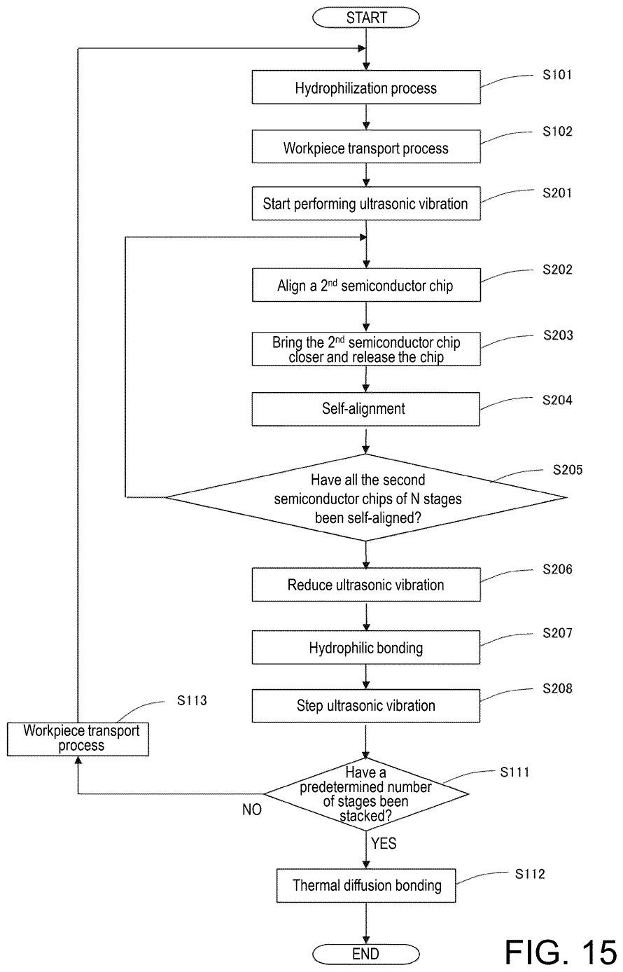

Next, referring to FIG. 15 to FIG. 17, another operation of the bonding apparatus 10 will be described. For operations similar to those described with reference to FIG. 3 to FIG. 14 above, the same step numbers are assigned and descriptions are omitted.

In the operation, multiple first semiconductor chips 22 loaded on the wafer 21 are ultrasonically vibrated, and the lower surfaces 23a of multiple second semiconductor chips 23 are brought close and released toward 22a the upper surfaces of each first semiconductor chip 22 so as to overlap with the first semiconductor chips 22 that are ultrasonically vibrating, thereby simultaneously self-aligning multiple second semiconductor chips 23 onto the first semiconductor chips 22, and reducing the ultrasonic vibration to simultaneously perform stacked bonding of the second semiconductor chips 23 onto the first semiconductor chips 22.

As shown in Step S102 of FIG. 15, the wafer 21 on which the three first semiconductor chips 221, 222, 223 are mounted is vacuum adsorbed onto the adsorption surface 11a of the stage 11, and three second semiconductor chips 231, 232, 233 are loaded on the loading stand 17.

In Step S201 of FIG. 15, the CPU 41 of the control part 40 of the bonding apparatus 10 starts ultrasonic vibration of the stage 11 by the ultrasonic vibrator 16. Accordingly, the three first semiconductor chips 221, 222, 223 mounted on the wafer 21 to start ultrasonic vibration.

In Step S202 of FIG. 15, the CPU 41 performs positioning of the first second semiconductor chip 231 to the first first semiconductor chip 221, and in Step S203 of FIG. 15, brings the second semiconductor chip 231 close to the first semiconductor chip 221, and releases the second semiconductor chip 231 from the collet 12. As a result, as shown in Step S204 of FIG. 3, the first second semiconductor chip 231 floats above the first first semiconductor chip 221 in a self-aligned state.

Next, in Step S205 of FIG. 15, the CPU 41 determines whether all the second semiconductor chips 23 of certain stages (N stages) N stages have been arranged in a self-aligned state. If determining as NO in Step S205 of FIG. 15, the CPU 41 returns to Step S202 of FIG. 15, positions the second second semiconductor chip 232 on the second first semiconductor chip 222, and in Step S203 of FIG. 15, executes approaching and releasing of the second semiconductor chip 232. As a result, the second second semiconductor chip 232 is arranged in a self-aligned state on the second first semiconductor chip 222.

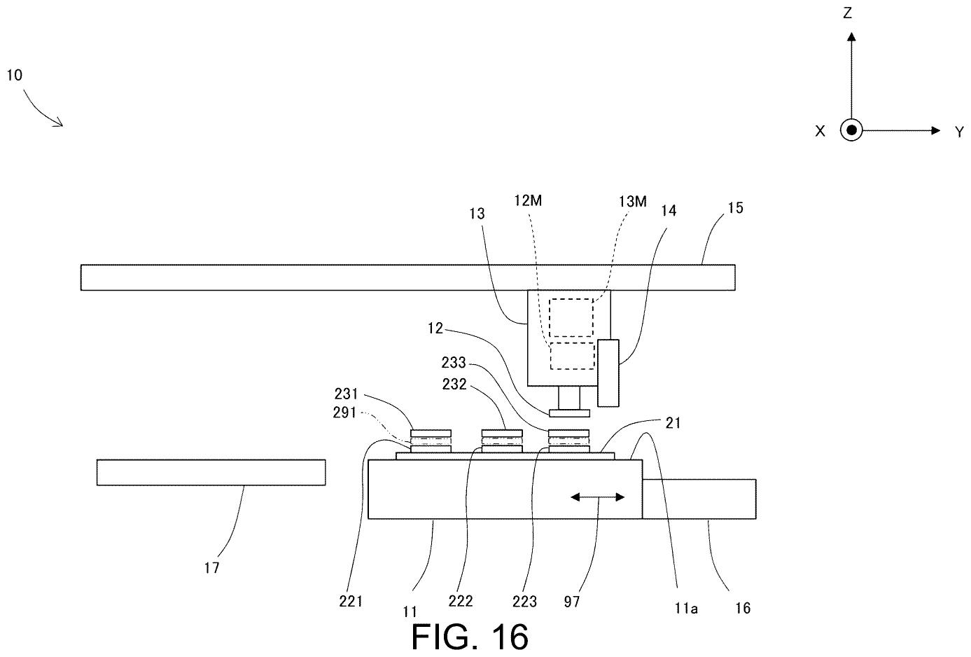

Similarly, the CPU 41 arranges the third second semiconductor chip 233 in a self-aligned state on the third first semiconductor chip 223. As a result, as shown in FIG. 16, the three second semiconductor chips 231 to 233 are simultaneously arranged in the self-aligned state on the three first semiconductor chips 221~223.

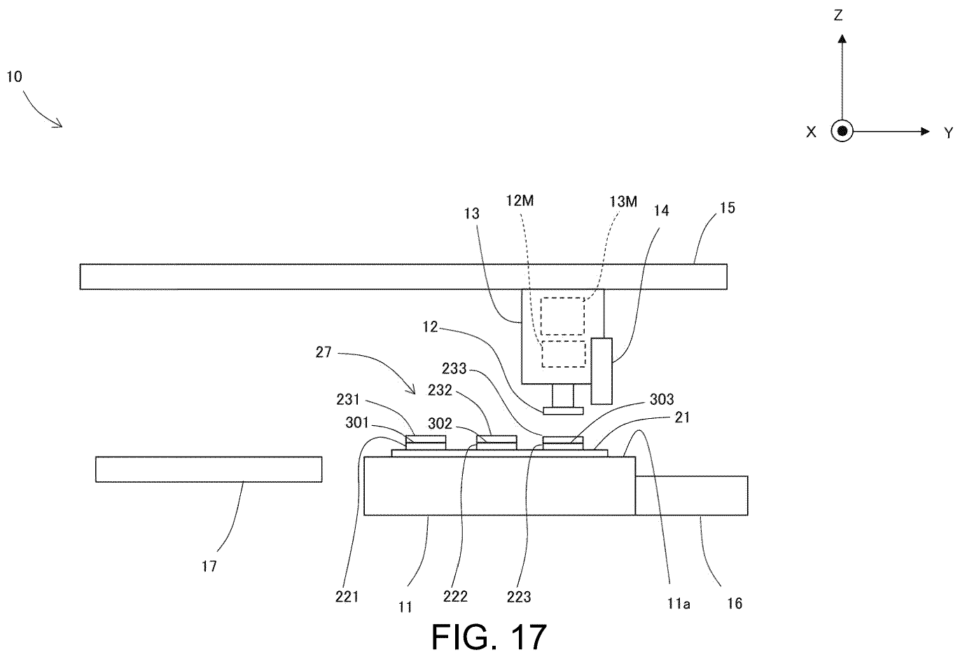

If determining YES in Step S205 of FIG. 15, the CPU 41 proceeds to Step S206 of FIG. 15 and gradually reduces the amplitude of the ultrasonic vibration of the ultrasonic vibrator 16. Then, the three second semiconductor chips 231, 232, 233 contact the first semiconductor chips 221, 222, 223 respectively due to gravity, and as shown in Step S207 of FIG. 15 and FIG. 17, and are respectively hydrophilically bonded at the respective junction surfaces 301, 302, 303. Then, in Step S208 of FIG. 15, the CPU 41 stops the ultrasonic vibration of the stage 11 by the ultrasonic vibrator 16.

As described above, the operation can simultaneously self-align the second semiconductor chips 23 on the first semiconductor chips 22 and bond the second semiconductor chips 23 and the first semiconductor chips 22 simultaneously. Additionally, since the ultrasonic vibration is not stopped during the period until the second semiconductor chips 23 are self-aligned on the respective first semiconductor chips 22, it is possible to suppress the adhesion of foreign matters on the first semiconductor chips 22 on which the second semiconductor chips 23 do not float, and the bonding quality can be improved.

The above describes other operations of the electronic component manufacturing system 100 and the bonding apparatus 10 of the embodiment, but the operations of Step S201 to Step S205 in FIG. 15 of the bonding apparatus 10 are a method for self-alignment of the second semiconductor chip 23 onto the first semiconductor chip 22. In addition, the operations of Step S206 to Step S208 in FIG. 15 of the bonding apparatus 10 are a bonding method for stacked bonding of the second semiconductor chips 23 onto the first semiconductor chips 22. Here, Step S201 in FIG. 15 is the ultrasonic vibration process of the bonding method, Step S202 and Step S205 in FIG. 15 are the self-alignment process of the bonding method, and Step S206 to Step S208 in FIG. 15 are the bonding process of the bonding method. Furthermore, Step S101 in FIG. 15 is the third hydrophilization process and the fourth hydrophilization process of the bonding method, Step S206 to Step S208 in FIG. 15 are the hydrophilic bonding process of the bonding method, and Step S112 in FIG. 15 is the thermal diffusion bonding process of the bonding method.

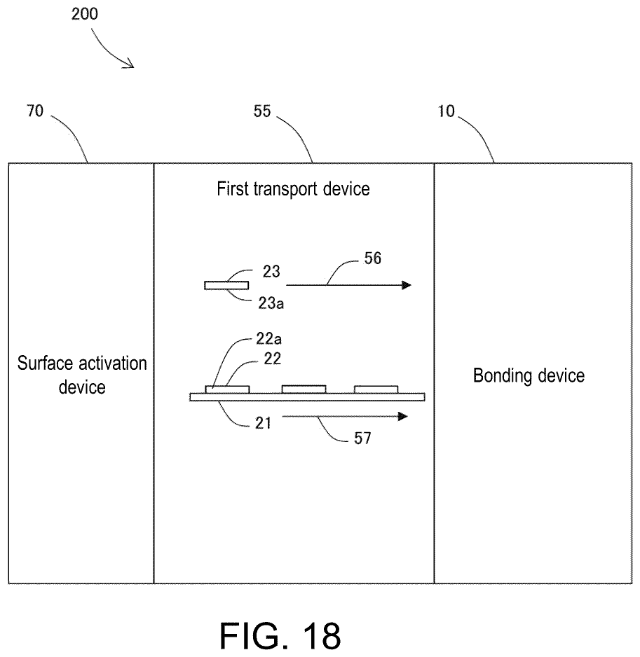

Next, referring to FIG. 18, another embodiment of an electronic component manufacturing system 200 will be described. The electronic component manufacturing system 200 bonds the first semiconductor chips 22 and the second semiconductor chips 23 by using surface activation bonding instead of hydrophilic bonding.

As shown in FIG. 18, the electronic component manufacturing system 200 is formed by a surface activation device 70, the first transport device 55, and the bonding apparatus 10.

The surface activation device 70 is, for example, a device that activates the surfaces of the upper surface 22a of the first semiconductor chip 22 and the lower surface 23a of the second semiconductor chip 23 by irradiating the surfaces with an inert argon atomic beam in a vacuum. The surface activation device 70 executes a first activation process that activates the upper surface 22a of the first semiconductor chip 22 and a second activation process that activates the lower surface 23a of the second semiconductor chip 23. Additionally, the bonding apparatus 10, after performing self-alignment of the second semiconductor chip 23, executes surface activation bonding by joining the activated lower surface 23a of the second semiconductor chip 23 to the activated upper surface 22a of the first semiconductor chip 22. At this time, the bonding apparatus 10 may be configured to perform surface activation bonding in a vacuum.

In the above description, the first semiconductor chip 22 and the second semiconductor chip 23 are described as having identical external shapes, but the invention is not limited thereto. The second semiconductor chip 23 may be larger than the first semiconductor chip 22 or, conversely, smaller than the first semiconductor chip 22, as long as the external shape of the second semiconductor chip 23 is similar to that of the first semiconductor chip 22.

Additionally, in the description, the wafer 21 loaded with the first semiconductor chips 22 is vacuum-adsorbed to the adsorption surface 11a of the stage 11, and the second semiconductor chips 23 are respectively stacked and bonded on the respective first semiconductor chips 22. However, the invention is not limited thereto. For example, a substrate loaded with multiple first semiconductor chips 22 may be vacuum-adsorbed to the adsorption surface 11a of the stage 11, and the second semiconductor chips 23 may be stacked and bonded. Furthermore, multiple first semiconductor chips 22 may be directly vacuum-adsorbed to the adsorption surface 11a of the stage 11, or vacuum-adsorbed via a holding jig, and the second semiconductor chips 23 may be stacked and bonded.

### REFERENCE SIGNS LIST

10 bonding apparatus, 11 stage, 11a adsorption surface, 12 collet, 12M Z-direction drive motor, 13 bonding head, 13M Y-direction drive motor, 14 camera, 15 guide rail, 16 ultrasonic vibrator, 17 loading stand, 21 wafer, 22, 221, 222, 223 first semiconductor chip, 22a, 221a, 23d upper surface, 23, 24, 25, 231, 232, 233 second semiconductor chip, 23a, 231a lower surface, 27 intermediate product, 28 electronic component, 40 control part, 41 CPU, 42 memory, 50 hydrophilization device, 55 first transport device, 60 heating device, 65 second transport device, 70 surface activation device, 75 metal thin film formation device, 100, 200, 300 electronic component manufacturing system, 221b, 231b electrode, 221c upper end surface, 231c lower end surface, 291 ultrasonic squeeze air film, 301, 302, 303 junction surface.

1. An alignment method, provided for a first semiconductor chip and a second semiconductor chip to be stacked and comprising:
ultrasonically vibrating the first semiconductor chip; and
bringing close a lower surface of the second semiconductor chip to an upper surface of the first semiconductor chip, so as to overlap with the first semiconductor chip that is ultrasonically vibrating, releasing the second semiconductor chip, and self-aligning the second semiconductor chip on the first semiconductor chip in a state in which the second semiconductor chip is floating from the upper surface of the first semiconductor chip.

2. The alignment method as claimed in claim 1,
wherein the first semiconductor chip and the second semiconductor chip have identical external shapes.

3. The alignment method as claimed in claim 2,
wherein in the ultrasonic vibrating, a plurality of the first semiconductor chips mounted on a wafer or a substrate are ultrasonically vibrated through ultrasonically vibrating the wafer or the substrate, and
in the self-aligning, an operation of bringing the lower surface of one of the second semiconductor chips close to the upper surface of one of the first semiconductor chips, so as to overlap with the one of the first semiconductor chips that is ultrasonically vibrating, and releasing the one of the second semiconductor chips is repetitively executed for each of the first semiconductor chips, and the second semiconductor chips are self-aligned on the first semiconductor chips.

4. A bonding method for stacking and bonding a second semiconductor chip on a first semiconductor chip, the bonding method comprising:
an ultrasonic vibrating step of ultrasonically vibrating the first semiconductor chip;
a self-aligning step of bringing close a lower surface of the second semiconductor chip to an upper surface of the first semiconductor chip, so as to overlap with the first semiconductor chip that is ultrasonically vibrating, releasing the second semiconductor chip, and self-aligning the second semiconductor chip on the first semiconductor chip in a state where the second semiconductor chip is floating from the upper surface of the first semiconductor chip; and
a bonding step of reducing ultrasonic vibration of the first semiconductor chip until the lower surface of the second semiconductor chip contacts the upper surface of the first semiconductor chip, and stacking and bonding the second semiconductor chip to the first semiconductor chip.

5. The bonding method as claimed in claim 4,
wherein the first semiconductor chip and the second semiconductor chip have identical external shapes.

6. The bonding method as claimed in claim 5,
wherein in the ultrasonic vibrating step, a plurality of the first semiconductor chips mounted on a wafer or a substrate are ultrasonically vibrated through ultrasonically vibrating the wafer or the substrate, and
in the self-aligning step, an operation of bringing the lower surface of one of the second semiconductor chips close to the upper surface of one of the first semiconductor chips, so as to overlap with the one of the first semiconductor chips that is ultrasonically vibrating, and releasing the one of the second semiconductor chips is repetitively executed for each of the first semiconductor chips, and the second semiconductor chips are self-aligned on the first semiconductor chips, and
in the bonding step, ultrasonic vibration of the wafer or the substrate is reduced until the respective lower surfaces of the respective second semiconductor chips contact the respective upper surfaces of the respective first semiconductor chips, and the respective second semiconductor chips are stacked and bonded to the respective first semiconductor chips.

7. The bonding method as claimed in claim 5, comprising:
a first hydrophilization step of hydrophilizing the upper surface of the first semiconductor chip; and
a second hydrophilization step of hydrophilizing the lower surface of the second semiconductor chip,
wherein the bonding step comprises: a hydrophilic bonding step of bonding by bringing the lower surface of the second semiconductor chip that is hydrophilized into contact with the upper surface of the first semiconductor chip that is hydrophilized; and a thermal diffusion bonding step of thermal diffusion bonding an electrode of the first semiconductor chip and an electrode of the second semiconductor chip by heating the first semiconductor chip and the second semiconductor chip that are hydrophilically bonded.

8. The bonding method as claimed in claim 6,
a third hydrophilization step of hydrophilizing each of the upper surfaces of a plurality of the first semiconductor chips mounted on the wafer or the substrate; and
a fourth hydrophilization step of hydrophilizing each of the lower surfaces of a plurality of the second semiconductor chips,
wherein the bonding step comprises: a hydrophilic bonding step of bonding by bringing the respective lower surfaces of the respective second semiconductor chips that are hydrophilized into contact with the respective upper surfaces of the respective first semiconductor chips that are hydrophilized; and a thermal diffusion bonding step of thermal diffusion bonding each electrode of each of the first semiconductor chips and each electrode of each of the second semiconductor chips by heating each of the first semiconductor chips and each of the second semiconductor chips that are hydrophilically bonded together with the wafer or the substrate.

9. The bonding method as claimed in claim 5,
a first activation step of activating the upper surface of the first semiconductor chip; and
a second activation step of activating the lower surface of the second semiconductor chip,
wherein in the bonding step, the lower surface of the second semiconductor chip that is activated is bonded to the upper surface of the first semiconductor chip that is activated through surface activation bonding.

10. An electronic component manufacturing device, provided for stacking and bonding a second semiconductor chip to a first semiconductor chip, the electronic component manufacturing device comprising:
a stage, provided for adsorption-fixing the first semiconductor chip to an adsorption surface on an upper side;
a collet, provided for holding and releasing the second semiconductor chip;
a bonding head, provided for moving the collet in a direction along the adsorption surface of the stage and a direction of approaching and departing from the adsorption surface;
an ultrasonic vibrator, provided for ultrasonically vibrating the stage; and
a control part, provided for adjusting an operation among the collet, the bonding head, and the ultrasonic vibrator,
wherein the control part comprises a processor for performing information processing, and
the processor is configured for:
ultrasonically vibrating the first semiconductor chip by ultrasonically vibrating the stage by using the ultrasonic vibrator;
moving the collet holding the second semiconductor chip to a position overlapping with the first semiconductor chip by using the bonding head and lowering the collet until a lower surface of the second semiconductor chip is close to an upper surface of the first semiconductor chip;
releasing the second semiconductor chip from the collet and self-aligning the second semiconductor chip onto the first semiconductor chip in a state where the second semiconductor chip is floating from the upper surface of the first semiconductor chip; and
reducing an output of the ultrasonic vibrator and bringing the lower surface of the second semiconductor chip into contact with the upper surface of the first semiconductor chip, and stacking and bonding the second semiconductor chip to the first semiconductor chip.

11. The electronic component manufacturing device as claimed in claim 10,
wherein the first semiconductor chip and the second semiconductor chip have identical external shapes.

12. The electronic component manufacturing device as claimed in claim 11,
wherein the stage is provided for adsorption-fixing a wafer or a substrate on which a plurality of the first semiconductor chips are mounted, and
the processor of the control part is configured for:
ultrasonically vibrating a plurality of the first semiconductor chips mounted on the wafer or the substrate by ultrasonically vibrating the stage by using the ultrasonic vibrator,
repetitively executing an operation of moving the collet holding one of a plurality of the second semiconductor chips to a position overlapping with one of the first semiconductor chips, lowering the collet until the collet is close to the upper surface of the one of the first semiconductor chips, and releasing the one of the second semiconductor chips from the collet, and self-aligning the second semiconductor chips onto the first semiconductor chips, and
reducing an output of the ultrasonic vibrator and bringing the respective lower surfaces of the respective second semiconductor chips into contact with the respective upper surface of the respective first semiconductor chips, and stacking and bonding the respective second semiconductor chips to the respective first semiconductor chips.

13. An electronic component manufacturing system, comprising the electronic component manufacturing device as claimed in claim 11, wherein the electronic component manufacturing system further comprises:
a hydrophilization device; and a heating device,
the hydrophilization device hydrophilizes the upper surface of the first semiconductor chip and the lower surface of the second semiconductor chip and supplies the first semiconductor chip and the second semiconductor chip to the electronic component manufacturing device,
the processor of the electronic component manufacturing device reduces an output of the ultrasonic vibrator to bring the lower surface that is hydrophilized in the second semiconductor chip into contact with the upper surface that is hydrophilized in the first semiconductor chip, and hydrophically bonds the first semiconductor chip and the second semiconductor chip, and
the heating device heats a bonded body in which the second semiconductor chip is hydrophilically bonded to the first semiconductor chip and thermal diffusion bonds an electrode of the first semiconductor chip and an electrode of the second semiconductor chip.

14. An electronic component manufacturing system, comprising the electronic component manufacturing device as claimed in claim 12, wherein the electronic component manufacturing system further comprises:
a hydrophilization device; and a heating device,
the hydrophilization device hydrophilizes the respective upper surfaces of the respective first semiconductor chips and the respective lower surfaces of the respective second semiconductor chip and supplies the first semiconductor chips and the second semiconductor chips to the electronic component manufacturing device,
the processor of the electronic component manufacturing device reduces an output of the ultrasonic vibrator to bring the respective lower surfaces that are hydrophilized in the respective second semiconductor chips into contact with the respective upper surfaces that are hydrophilized in the respective first semiconductor chips, and hydrophically bonds the respective first semiconductor chips and the respective second semiconductor chips, and
the heating device heats a bonded body in which each of the second semiconductor chips is hydrophilically bonded to each of the first semiconductor chips and thermal diffusion bonds each electrode of each of the first semiconductor chips and each electrode of each of the second semiconductor chips.
